(19) United States
(12) Patent Application Publication
(10) Pub. No.: US 2008/0309913 A1
(43) Pub. Date: Dec. 18, 2008

(54) SYSTEMS AND METHODS FOR LASER RADAR IMAGING FOR THE BLIND AND VISUALLY IMPAIRED

(76) Inventor: James John Fallon, Armonk, NY (US)

Correspondence Address: Kristina M. Grasso;Kristina M. Grasso, Esq. PLLC, P.O. Box 162, Milford, NH, 03055, US

(21) Appl. No.: 12/139,828

(22) Filed: Jun. 16, 2008

Related U.S. Application Data
(60) Provisional application No. 60/934,990, filed on Jun. 14, 2007.

(51) Int. Cl. G01C 3/08; H01L 25/00

(52) U.S. Cl. 356/4.01; 250/332

(57) ABSTRACT

A 3D imaging ladar system comprises a solid state laser and geiger-mode avalanche photodiodes utilizing a scanning imaging system in conjunction with a user interface to provide 3D spatial object information for vision augmentation for the blind. Depth and located object information is presented acoustically by: 1) generating an audio acoustic field to present depth as amplitude and the audio image as a 2D location. 2) holographic acoustical imaging for a 3D sweep of the acoustic field. 3) a 2D acoustic sweep combined with acoustic frequency information to create a 3D presentation.

A system to fuse data derived from a three dimensional imaging ladar system with information from a visible, ultraviolet, or infrared camera systems and acoustically present the information in a four or five dimensional acoustical format utilizing three dimensional acoustic position information, along with frequency, and modulation to represent color, texture, or object recognition information is also provided.

### RELATED US APPLICATION DATA

This application claims the benefit of U.S. Provisional Patent Application No. 60/934,990 filed on Jun. 14, 2007, which is incorporated by reference herein in its entirety.

### BACKGROUND OF THE INVENTION

The present invention relates generally to vision augmentation and, more particularly, to systems and methods for providing a three dimensional vision replacement and augmentation for the blind and visually impaired.

The World Health Organization estimates that in 2002 approximately 161 million (2.6% of the world's population) are visually impaired, of which 124 million (2.0%) have significantly impaired vision and 40 million are blind. According to the American Foundation for the Blind there are approximately 10 million blind and visually impaired people in the United States of which approximately 1.3 million Americans are legally blind. The legal definition of blindness refers to central visual acuity of 20/200 or less in the better eye with the best possible correction, as measured on a Snellen vision chart, or a visual field of 20 degrees or less

Of the estimated 40+ million blind people located around the world, 70-80% can have some or all of their sight restored through treatment while the remaining percentage have untreatable diseases such as macular degeneration, glaucoma, and diabetic retinopathy or have lost some or all their vision due to eye injuries (a leading cause of monocular blindness), occipital lobe brain injuries, genetic defects, poisoning, or willful acts.

According to the World Health Organization blindness and other forms of visual impairment originate from a variety of sources including diseases and malnutrition. The most common causes of blindness are cataracts 47.8% (an opacity that develops in the lens of the eye or in its envelope), glaucoma 12.3% (various diseases of the optic nerve involving loss of retinal ganglion cells in a characteristic pattern of optic neuropathy), uveitis 10.2% (an inflammation of the middle layer of the eye, the “uvea”), macular degeneration 8.7% (predominantly found in elderly adults in which the center of the inner lining of the eye, known as the macula area of the retina, suffers thinning, atrophy, and in some cases bleeding), corneal opacity 5.1%, diabetic retinopathy 4.8%, and trachoma 3.6%. With ever increasing life expectancies and over half of the 10 million visually impaired in the United States over age 60, it is anticipated that age related visual impairment and blindness will unfortunately continue to increase.

Visually impaired and blind people have devised a number of techniques that allow them to complete daily activities using their remaining senses. These might include one or more of the following: adaptive computer and mobile phone software that allows people with visual impairments to interact with their computers and/or phones via screen readers or screen magnifiers; and adaptations of banknotes so that the value can be determined by touch. For example: in some currencies, such as the euro, the pound sterling and the Norwegian krone, the size of a note increases with its value. Many banknotes from around the world have a tactile feature to indicate denomination in the upper right corner. This tactile feature is a series of raised dots, but it is not standard Braille. It is also possible to fold notes in different ways to assist recognition.

Other typical innovations include labeling and tagging clothing and other personal items, placing different types of food at different positions on a dinner plate, and marking controls of household appliances. Most people, once they have been visually impaired for long enough, devise their own adaptive strategies in all areas of personal and professional management.

Most visually impaired people who are not totally blind read print, either of a regular size or enlarged by magnification devices. Many also read large-print, which is easier for them to read without such devices. A variety of magnifying glasses, some handheld, and some on desktops, can make reading easier for them.

The remainder read Braille (or the infrequently used Moon type), or rely on talking books and readers or reading machines. They use computers with special hardware such as scanners and refreshable Braille displays as well as software written specifically for the blind, such as optical character recognition applications and screen readers.

Some people access these materials through agencies for the blind, such as the National Library Service for the Blind and Physically Handicapped in the United States, the National Library for the Blind or the RNIB in the United Kingdom. Closed-circuit televisions, equipment that enlarges and contrasts textual items, are a more high-tech alternative to traditional magnification devices. So too are modern web browsers, which can increase the size of text on some web pages through browser controls or through user-controlled style sheets.

Access technology, such as screen readers and screen magnifiers, enable the blind to use mainstream computer applications. Most legally blind people (70% of them across all ages, according to the Seattle Lighthouse for the Blind) do not use computers. Only a small fraction of this population, when compared to the sighted community, have Internet access. This bleak outlook is changing, however, as availability of assistive technology increases, accompanied by concerted efforts to ensure the accessibility of information technology to all potential users, including the blind. Later versions of Microsoft Windows include an Accessibility Wizard & Magnifier for those with partial vision, and Microsoft Narrator, a simple screen reader. Linux distributions for the blind include Oralux and Adriane Knoppix, the latter developed in part by Adriane Knopper who has a visual impairment. The Macintosh OS also comes with a built-in screen reader, called VoiceOver.

The movement towards greater web accessibility is opening a far wider number of websites to adaptive technology, making the web a more inviting place for visually impaired surfers. Experimental approaches in sensory substitution are beginning to provide access to arbitrary live views from a camera.

Perhaps the biggest deficiency in the current art is in the area of mobility assistance. Many people with serious visual impairments currently travel independently assisted by tactile paving and/or using a white cane with a red tip—the international symbol of blindness.

A long cane may used to extend the user's range of touch sensation, swung in a low sweeping motion across the intended path of travel to detect obstacles. However, some visually impaired persons do not carry these kinds of canes, opting instead for the shorter, lighter identification (ID) cane. Still others require a support cane. The choice depends on the individual's vision, motivation, mobility, and other factors.

Each of these is typically painted white for maximum visibility, and to denote visual impairment on the part of the user. In addition to making rules about who can and cannot use a cane, some governments mandate the right-of-way be given to users of white canes or guide dogs.

Ellis in U.S. Pat. No. 5,973,618 presents a portable safety mechanism housed in a cane, a walking stick or a belt-carried housing. In each of such embodiments, the portable safety mechanism includes a processor, a transmitter, a receiver, and an outside image sensor or scanner, a warning device such as an audible warning device or warning light. The scanner may, for example, sense the shape of a traffic signal or the color of a traffic signal.

Several manufacturers have adapted this type of technology to sonar based walking canes. For example the Sonar Traveler Cane is a new electronic travel aid for blind travelers developed by Harold Carey and Ryan McGirr a staff member of the National Federation of the Blind. Utilizing sonar technology, the traveler cane will warn the blind user of low hanging objects, construction supports, and other objects that a cane alone would not detect. Distance to an object can be determined to allow a blind person to better navigate a crowded hallway, bank teller line, or supermarket line, or to discreetly locate an empty row and seat at a stadium.

It should be noted that this particular type of sonar cane does not replace the standard functionality of the cane. For example, the sonar will not notify the traveler about drop offs or steps, it requires the traditional use of the cane will already accomplish this. Instead the electronics in the cane target the areas where the cane cannot detect; for instance, the area above the waist and below the head. By notifying the traveler with a strong pulse from the vibrating motor, he or she has plenty of time to react before a potentially painful collision. The sonar cane automatically enters obstacle detection mode without any buttons or switches to press whenever the cane is held at an angle, as when the user is walking forward.

The other mode of the Sonar Traveller Cane is called the distance finder mode. The cane automatically switches to this mode whenever the cane is held vertical. Distance Finder mode is useful for determining distances to objects, and is helpful in situations such as navigating a line, and being notified when the line moves. It can also find gaps in a crowd, open doors on a bus, or any other situation where you would like to know the distance to an object.

Distance to the object is determined through the frequency that the motor pulses. The closer the object is to the cane, the more rapid the pulses. This signal can also be inverted by flipping the lower switch on the cane. In this mode, the motor will not pulse for close objects, and will pulse more rapidly for distant objects. This mode is called queue-minder mode, and it is particularly useful in lines. With the sonar pointed at the person close in front of you in line, the motor will be completely silent. It will start to pulse as the person in front starts to move forward, signaling it is time to advance. When you move forward and close the gap the motor will fall silent again, letting you know you have moved up into correct position

The Sonar Traveller Cane is lightweight, with most of the weight being from the four AAA batteries. The batteries should last at least 11 hours, and are rechargeable using the included charger in less than 3 hours. All feedback from the cane is provided through a quiet vibrating motor, leaving you free to better hear your surroundings. The Sonar Traveller cane is easy to use and offers intuitive feedback. Most people are able to use the cane effectively in less than 5 minutes. After a little practice, the additional feedback provided by the cane will offer you many advantages over a standard cane, and you will find that you become a better and more confident traveler because of it.

Another manufacturer of Sonar walking sticks, ‘K’ sonar, also enables blind persons to perceive their environment through ultrasound and be more mobile in their need to travel. The ‘K’ Sonar has been designed to be attached to a long cane. It also can be used without the cane as an independent travel aid for those who have learned to use it well in suitable, familiar, recognizable situations. The ‘K’ Sonar works like an ordinary flashlight except that it sends out a beam of sound rather than light. Silent ultrasonic waves bounce off objects sending back information about objects and their location. Sonar information is collected from the path ahead by the ‘K’ Sonar providing a mental map of objects in front and to the sides of the user as the cane is scanned. The tip of the cane acts as a safety backstop by coming into contact with an object that was not avoided.

Scanned objects normally produce multiple echoes, translated by the ‘K’ Sonar receiver into unique invariant ‘tone-complex’ sounds, which users listen to and learn to recognize. The human brain is very good at learning and remembering these sound-signature sequences in a similar way that it learns a musical tune. The sound signatures vary according to how far away the ‘K’ Sonar is from the object, thus indicating distance. The user listens to these sounds through miniature earphones and can detect the differences between sound sequences thus identifying the different objects.

The combination of the cane and the ‘K’ Sonar together is an advancement in independent travel by blind and visually impaired people. This combination removes some of the limitations of either aid by itself. The ‘K’ Sonar provides earlier warnings of surrounding obstacles than the cane can provide. This helps to avoid them more smoothly and provides good identification of objects that makes navigation much easier than with only a cane.

The ‘K’ Sonar uses KASPA Technology to mimic the bat's sonar capability of gathering rich spatial information about the surrounding environment. In a similar way to a person recognizing the texture of different surfaces through their fingertips, sonar echoes, as heard in miniature headphones, carry object texture information to the brain. KASPA Technology has been studied in parallel with animal sonar studies for over 40 years.

Some pulse-echo sensors also claim to model the bat sonar. However, they can only do this in a crude way by using a simple tone pulse, as the ultrasonic emission, in order to receive a detectable echo from the nearest object. The bat and the ‘K’ Sonar both emit similar frequency chirps, and multiple objects can be detected and recognized.

Learning is relatively easy since the user's brain seems to accept and process sonic information remarkably well. The brain learns the sound signature sequences created when walking, as if it were learning and remembering a musical tune. Users can recognize environmental changes along a known route by referring to their memory of that route's “sound patterns”.

This ability is not in-built. Learning how to use the ‘K’ Sonar can vary between the users. However, the basic understanding of object presence, distance and direction can be picked up very quickly. This process has been classed as extremely intuitive.

However, one significant limitation within the current art is that ultrasonic vision augmentation devices possess extremely poor spatial resolution and working distances. Ultrasound transmission is air is greatly attenuated at higher frequencies and higher frequencies are required for better spatial resolution. Resolutions are quite poor, typically six degrees at best.

Another limitation within the current art is the need to manually switch between short and long distance modes of operation to garner reasonable user information.

Yet another limitation within the current art is the need to manually scan the ultrasonic device, typically in the horizontal direction, to discern object location within the field of view. However a two dimensional detailed spatial distance map is not possible with the current technology.

Yet another limitation within the current art is the limited overall total field of view of the ultrasonic device which mandates manual scanning.

Yet another limitation within the current art is the need for continued use of a cane for orientation and mobility in conjunction with the ultrasonic device.

Guide dogs are assistance dogs trained to lead blind or vision impaired people around obstacles. Although trademarked, the name of one of the more popular training schools for such dogs, The Seeing Eye, has entered the vernacular as the genericized term “seeing eye dog” in the US. Dog are quite useful as they can hear as well as see.

One limitation within the current art is that guide dogs may become distracted while performing their duties by loud noise or other types of events.

Another limitation within the current art is that guide dogs need extensive training, maintenance, and re-certification.

Another limitation of guide dogs is that although the dogs can be trained to navigate various obstacles, they are partially (red-green) color blind and are not capable of interpreting street signs. The human half of the guide dog team does the directing, based upon skills acquired through previous mobility training. The handler might be likened to an aircraft's navigator, who must know how to get from one place to another, and the dog is the pilot, who gets them there safely.

Optical radars (often referred to as ladar or lidar), possess an inherently much shorter wavelength of operation than ultrasound systems. Optical radars may utilize visible, ultraviolet, or infrared light sources which propagate as electromagnetic waves instead of ultrasound, which requires molecular vibration in a fluid or gas. Hence, optical radars can resolve objects subtending a smaller angular field of view that provide highly accurate range measurement to multiple points of view creating a highly accurate three dimensional image.

Current imaging ladar systems utilize a single point source of modulated laser light and a single detector along with scanning optics. The laser sends out multiple light pulses, each directed to a different point in the scene by the scanning mechanism, and each resulting in a range measurement obtained by using a single detector. Scanners are typically based upon piezoelectric or galvanometer technology, which places restrictions on the speed and inherent accuracy of image acquisition.

Limitations within the current art include the excessive size and weight of modern ladar systems, along with the volume, power, and costs of the system.

Accordingly, there is a strong and compelling need for a vision augmentation system that would address limitations in the existing art as described above.

### SUMMARY OF THE INVENTION

This invention is directed to portable three dimensional imaging ladar systems utilized in conjunction with a near-field user interface to provide highly accurate three dimensional spatial object information for vision augmentation for the blind or visually impaired.

In addition, a three dimensional imaging ladar system is utilized in conjunction with a user interface to provide highly accurate three dimensional spatial object information for vision augmentation for the blind or visually impaired.

It is one goal of the present invention to overcome the limitations of the present vision augmentation and mobility techniques.

It is a goal of the present invention to provide a system and method to locate objects in the scene by a three dimensional imaging ladar system comprised of one or more solid state lasers and one or more geiger-mode avalanche photodiodes utilizing a static imaging system and a user interface.

It is another goal of the present invention to provide a system and method to locate objects in the scene by a three dimensional imaging ladar system comprised of a one or more solid state lasers and one or more geiger-mode avalanche photodiodes utilizing a scanning imaging system and a user interface.

It is yet another goal to provide a system and method for a vision augmentation system that presents depth information and located object information acoustically by generating an audio acoustic field to present depth as amplitude and the audio image as two dimensional location.

It is a further goal to provide a system and method for a vision augmentation system that presents depth information and located object information utilizing holographic acoustical imaging for the three dimensional sweeps of the acoustic field.

It is yet a further goal to provide a system and method for a vision augmentation system that presents depth information and located object information utilizing a two dimensional acoustic sweep combined with acoustic frequency or intensity information to create a three dimensional presentation.

It is an additional goal to provide a system and method to fuse data derived from a three dimensional imaging ladar system with information from a visible, ultraviolet, or infrared camera systems and acoustically present the information in a four or five dimensional acoustical format utilizing three dimensional acoustic position information, along with frequency, and modulation to represent color, texture, or object recognition information.

### BRIEF DESCRIPTION OF THE DRAWINGS

The above and other objects and advantages of the present invention will be apparent upon consideration of the following detailed description, taken in conjunction with accompanying drawings, in which like reference characters refer to like parts throughout, and in which:

FIG. 1 is a block diagram of a vision augmentation system comprised of three dimensional imaging ladar system that presents spatial information to the user by a user interface, according to one embodiment of the present invention;

FIG. 2 is a flow diagram of a vision augmentation system comprised of a three dimensional imaging ladar system that presents spatial information to the user by a user interface, according to one embodiment of the present invention;

FIG. 3 is a block diagram of a vision augmentation system comprised of a three dimensional imaging ladar system comprised of a short pulse laser and geiger-mode avalanche photodiodes utilizing a static imaging system and a user interface, according to another embodiment of the present invention;

FIG. 4 is a block diagram of a vision augmentation system comprised of ladar system comprised of a short pulse laser and geiger-mode avalanche photodiodes utilizing a scanning imaging system and a user interface, according to another embodiment of the present invention;

FIG. 5 is a yet another block diagram of a vision augmentation system comprised of a three dimensional imaging ladar system comprised of a short pulse laser and geiger-mode avalanche photodiodes utilizing a scanning imaging system and a user interface, according to another embodiment of the present invention;

FIG. 6 is a block diagram of three dimensional object or surface information presented to a user via a user interface by generating an audio acoustic field that presents depth as audio intensity audio image as location, according to another embodiment of the present invention;

FIG. 7 is a block diagram of three dimensional object or surface information presented to a user via a user interface by generating a holographic audio acoustic field that presents depth as audio intensity audio image as location, according to another embodiment of the present invention;

FIG. 8 is a block diagram of a vision augmentation system that fuses data derived from a three dimensional imaging ladar system with information from a visible, ultraviolet, or infrared camera system in accordance with yet another embodiment of the present invention;

FIG. 9 is a block diagram of three dimensional object or surface information presented to a user via a user interface by generating a audio acoustic field that presents depth as audio intensity, audio image as location, along with frequency to represent color, and modulation to represent texture or object information according to another embodiment of the present invention.

FIG. 10 is a block diagram of a vision augmentation system that fuses data derived from a three dimensional imaging ladar system with information from a visible, ultraviolet, or infrared camera system, along with gyros, accelerometers, global positioning systems, and other attitude or position locators in accordance with yet another embodiment of the present invention.

### DETAILED DESCRIPTION OF THE PREFERRED EMBODIMENTS

The present invention is directed to systems and methods for providing vision augmentation and, more particularly, to systems and methods for providing a three dimensional vision replacement and augmentation for the blind and visually impaired.

In the following description, it is to be understood that system elements having equivalent or similar functionality are designated with the same reference numerals in the figures. It is to be further understood that the present invention may be implemented utilizing a wide variety of components including, but not limited to light emitting diodes and solid state lasers, solid state imaging array detectors that operate in the ultraviolet, visible, infrared wavelengths, static and scanning optical systems, image processing and recognition hardware and software, general purpose and digital signal processors, hardware, software, and firmware for system functionality including user interface, data processing, and databases, portable power sources, along with user interfaces that utilize vision, sound, touch, smell, taste, thermoception (the sense of heat or the absence thereof), nociception (the non-conscious perception of near-damage or damage to tissue), equilibrioception (the perception of balance or acceleration) and proprioception (the perception of body awareness).

It is to be further understood that the actual system connections shown in the figures may differ depending upon the manner in which the systems are configured or programmed. Given the teachings herein, one of ordinary skill in the related art will be able to contemplate these and similar implementations or configurations of the present invention.

Although illustrative embodiments have been described herein with reference to the accompanying drawings, it is to be understood that the present invention is not limited to those precise embodiments, and that various other changes and modifications may be affected therein by one skilled in the art without departing from the scope or spirit of the invention. All such changes and modifications are intended to be included within the scope of the invention as defined by the appended claims.

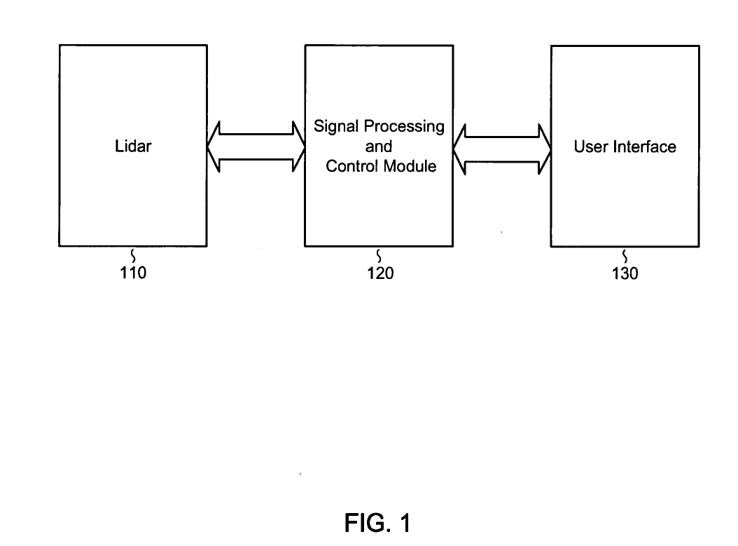

Referring now to FIG. 1, a block diagram illustrates a visual augmentation system comprised of three dimensional imaging ladar system that presents spatial information to the user by a user interface. The system includes a lidar system 110, signal processing and control module 120, and a user interface 130.

The lidar system 110 employs an optical remote sensing technology that measures properties of scattered light to find range and/or other information of remote surfaces or objects. One method to determine distance to an object or surface is to use laser pulses and the range is determined by measuring the time delay between transmission of a pulse and detection of the reflected signal. In many ways similar to radar technology, however radar utilizes radio waves instead of light. Advantageously, lidar utilizes much shorter wavelengths of the electromagnetic spectrum, typically in the ultraviolet, visible, or infrared. This provides higher resolution since the wavelength employed is directly proportional to resolution.

In order to be sensed by an electromagnetic wave, an object needs to produce a dielectric discontinuity in order to reflect the transmitted wave. At radar (microwave or radio) frequencies metallic objects produce a significant reflection. However non-metallic objects, such as rain and rocks produce weaker reflections and some materials may produce no detectable reflection at all, meaning some objects or features are effectively invisible at radar frequencies. This is especially true for very small objects (such as single molecules and aerosols). In addition, man portable radar systems would cause health hazards when used in populated areas or to the end user due to human absorption of the radar waves.

Ultrasonic solutions have a similar and more severe problem. Acoustic waves are easily absorbed by many surfaces and in a perfectly anechoic environment, ultrasound solutions are inoperable. This limits the effective range of ultrasound solutions unless excessive transmitted power is utilized.

In the present invention, lidar systems equipped with lasers provide one solution to these problems. The beam densities and coherency are excellent. Moreover the wavelengths are much smaller than can be achieved with radio or ultrasound systems, and range from about 10 micrometers to the ultraviolet (250 nm). At such wavelengths, the waves are “reflected” very well from small objects. This type of reflection is called backscattering. Different types of scattering are used for different lidar applications, most common are Rayleigh scattering, Mie scattering and Raman scattering as well as fluorescence. A laser typically has a very narrow beam which allows the mapping of physical features with very high resolution compared with radar or ultrasound. In addition, many chemical compounds interact more strongly at visible wavelengths than at microwaves, resulting in a stronger image of these materials. Suitable combinations of one or more lasers, or tuning of laser frequencies, can allow for remote mapping of atmospheric contents by looking for wavelength-dependent changes in the intensity of the returned signal, hence the present invention is also capable of detecting smoke and other hazards in the operational field of view.

One preferred embodiment of the present invention employs a micro pulse lidar due to their modest consumption of power, allowing for portable operation, and modest energy output in the laser, typically on the order of one micro joule, providing “eye-safe” operation, thus allowing them to be used without safety precautions.

Another embodiment of the present invention utilizes co-operative retro reflectors or reflective coatings on one or more objects in the field of view. This is useful when objects in the field of view have high transparency or very emissivities within a specific spectral band.

The lidar system 110 is operatively connected to the signal processing and control module 120 that is comprised of one or more of the following: dedicated analog or digital hardware, digital signal processors, general purpose processors, software, firmware, microcode, memory devices of all forms, and data input or output interfaces. The signal processing and control module 120 provides command and control information such as synchronization information to and active illumination, sensors, scanning systems, optics (such as, but not limited to, focus adjustment, field of view selection, operating spectral band or filter selection), acceptance of lidar or camera scene image information, and processes the information into one or more formats, such as acoustical information, for the user interface. In addition, the signal processing and control module 120 may provide housekeeping information or accept commands on various component health or maintenance information, for example remaining battery power, laser life, and system configuration information. This information may be presented via its own dedicated interface, or may be interfaced to a network by a wired or wireless interface for storage, transmission, or display. In addition, the housekeeping and command interface may utilize the user interface 130, either exclusively or in combination with the housekeeping and command interface. For example, one or more unique acoustical signatures may be sent to the user interface 130 to signal a low battery, system degradation or failure, or improper system configuration.

The signal processing and control module 120 is operatively connected to the user interface 130 that presents spatial location information and a optionally additional information on the scene such as color, texture, emissivity, or temperature via sound, touch, smell, taste, thermoception (the sense of heat or the absence thereof), nociception (the non-conscious perception of near-damage or damage to tissue), equilibrioception (the perception of balance or acceleration) and proprioception (the perception of body awareness. In addition, a visual display may be utilized with corrective optics or visually enhanced display for those with limited sight or other visual impairments.

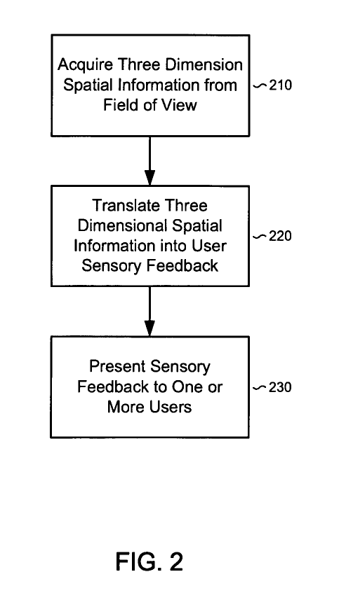

Referring now to FIG. 2, a flow diagram of a visual augmentation systems is comprised of the steps of acquiring three dimensional spatial information from one or more fields of view 210, translating the three dimensional spatial information into a form suitable for user sensory feedback 220, and present the spatial information in a suitable form via one or more user interfaces to one or more users 230. By way of example, two visually impaired individuals are walking through a hallway together, one individual is wearing the present invention, affixed to eyeglasses, that acquires three dimensional spatial information from the forward field of view per step 210, translates the three dimensional spatial information into a form suitable for user sensory feedback per step 220, and provides an acoustic three dimensional spatial information to the user wearing the eyeglasses with the affixed invention per earphones connected via a wired interface, along with transmitting the information to a second user via earphones and a visually enhanced display via a wireless transmitter in the present invention and wireless receivers in the earphones and visually enhanced display.

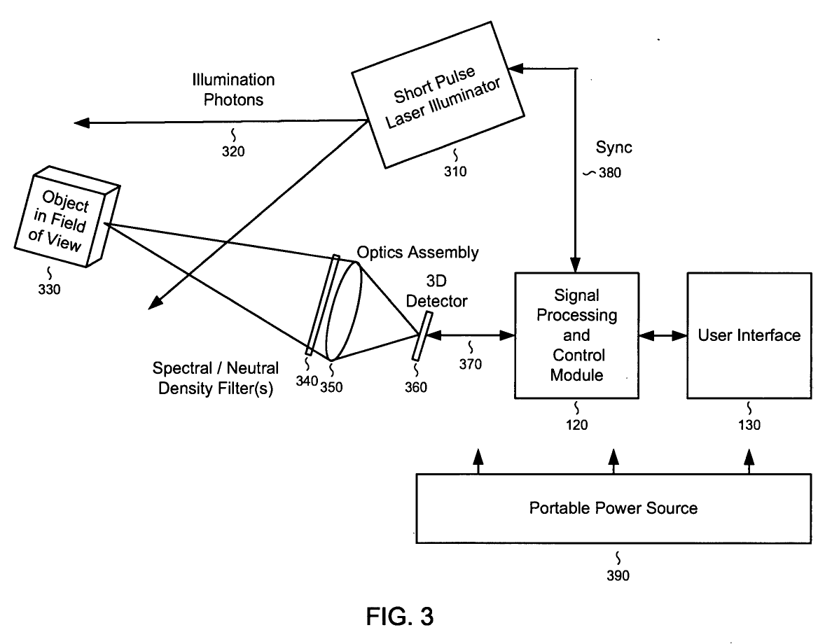

Referring now to FIG. 3, a block diagram of a vision augmentation system is comprised of a short pulse laser illuminator 310 that provides illumination photons 320 to a field of view. In order to generate a short pulse the laser illuminator may utilize passive Q-switching. Advantageously, Passively Q-switched frequency-doubled Nd:YAG (neodymium-doped yttrium-aluminum-garnet) microchip lasers have been developed that produce very short (250 picosecond) optical pulses at 532 nm, with pulse energies of 30 μJ or better. The microchip laser systems, including power supply, are very compact and utilize very small amounts of power. This microchip laser fulfills the requirements for our imaging ladar transmitter: a small package that delivers many photons in a very short pulse.

In addition the short pulse laser illuminator many utilize 600-1000 nm lasers that are common for non-scientific applications. They are inexpensive but since they can be focused and easily absorbed, maximum power must be limited to make them eye-safe. Eye-safety is often a requirement for most applications. 1550 nm lasers are eye-safe at much higher power levels since this wavelength is not focused by the eye, but the short wave infrared detector technology is less advanced, however it is anticipated that future developments will allow these wavelengths to be uses at longer ranges and slightly lower accuracies. It should be noted that the present invention is not limited to a single wavelength, indeed is anticipated that multispectral solutions utilizing tunable sources, broadband sources with narrowband filters, or multiple narrowband sources may be employed. One advantage of utilizing multiple sources, per the present invention, is to allow for detection of transparent or semi-transparent surfaces that may be difficult to detect at the visible wavelengths but easily detected at UV or infrared wavelengths.

A key attribute of short pulse laser illuminator 310, is the laser repetition rate (which is related to data collection speed). Pulse length is generally an attribute of the laser cavity length, the number of passes required through the gain material (YAG, YLF, etc.), and Q-switch speed. Better target resolution is achieved with shorter pulses, provided the lidar receiver detectors and electronics have sufficient spatial and temporal bandwidth. Specific factors that contribute to the selection of the short pulse illumination source include, but are not limited to, optical flux energies and emission wavelengths, mean time between failure at various output levels, power consumption, thermal requirements, volumetric profile, along with availability and cost.

The short pulse laser illuminator 310 may utilize one or more optical elements to illuminate the field of view. A beam expander is one such device, as is a wide angle “fisheye” lens. All other forms of optical systems are equally applicable such as scanning systems which employ a laser pulse illuminated instantaneous field of view that is scanned or directed into a larger operational field of view.

Typically a laser pulse is generated either synchronously or the timing of the pulse is known within a reasonable degree of accuracy. The illumination photons 320 are impingent upon an object or surface in the field of view and are either reflected, transmitted, or absorbed by the object or surface. Reflected photons that are backscattered in the optics assembly's field of view are received by the optical system 350 comprised of any number of optical elements or limiting apertures or scan mechanisms. One or more spectral filters 340 may be utilized to reject background photons and only allow in photons reflected back from the short pulse laser illuminator. In addition, the spectral filter other forms of filters may be utilized such as neutral density filters which attenuate photons from many wavelengths and synchronous shutter mechanisms utilizing liquid crystals, epaper/e-ink technology, electrostatic shutters, or all other forms of shutter and chopper mechanisms. In addition, a shutter may be utilized for protection against high energy sources (such as direct sunlight) or foreign objects and contamination.

The optical assembly 350 may be any form of optical system that is capable of collecting the photons within the desired field of view and presenting them to one or more detectors 360 employed in the present invention. In addition, the optical elements including means for scanning, lenses, mirrors, apertures, spectral filters, and detectors may be combined in any manner or order that meet the needs of the present invention.

The optical system may provide for a fixed field of view or a variable field of view. If the field of view is variable it may be varied periodically, or in accordance to some prescribed sequence, or by user input, or some combination thereof. In addition, the optical system need not have the same resolution over the entire field of view. It is well known that although the human eye receives data from a field of about 200 by 200 degrees, the acuity over most of that range is quite poor. The retina, which is the light-sensitive layer at the back of the eye, covering about 65 percent of its interior surface, possesses photosensitive cells called rods and cones that convert incident light energy into signals that are carried to the brain by the optic nerve. In the middle of the retina is a small dimple called the fovea centralis. It is the center of the eye's sharpest vision and the location of most color perception. To form high resolution images, the light impingent on the eye must fall on the fovea, which limits the acute vision angle to about 15 degrees. Under low level light conditions viewing is even worse, the fovea has sensitivity limitations since it is comprised entirely of cones, requiring the eye to be slightly off-axis.

In one preferred embodiment of the present invention, a variable resolution optical system is employed to effectively parody the human visual system. Alternatively, a variable size and resolution of the field of view may be employed. The change of the field of view may be autonomous, by recognition of a object or image attribute, by user command, such as a voice command or eye, head, or body movement or any other form of user input.

In addition, the optical system may include auto focusing to accommodate a broad range of surface or object depths that might be encountered in the field of view, and/or image stabilization to prevent errors due movement of the user or mounting platform. Such techniques are widely known in the still and video camera art.

The optical system 350 collects one or more photons and presents these photons to a detector 360 capable of resolving spatial depth information. Such detectors have been recently developed in low cost array formats utilizing existing metal-oxide semiconductor (CMOS) technology that is similar to the technology currently utilized in digital video camcorders and digital cameras. In specific, a detector based upon arrays of geiger mode avalanche photodiodes (APDs) integrated with fast CMOS time-to-digital converter circuits have been developed. Geiger mode is a technique of operating an APD so that it produces a fast electrical pulse of several volts amplitude in response to the detection of even a single photon. With simple level shifting, this pulse can trigger a digital CMOS circuit incorporated into the pixel. Single-photon sensitivity is achieved along with sub-nanosecond timing precision. Because the timing information is digitized in the pixel circuit, it is read out noiselessly. The timing of the photon from leaving the short pulse laser illuminator 310 until it is backscattered from a surface in the field of view 330 and reaches the detector is proportional to twice the distance from the short pulse laser 310/detector 360 pair to the surface. In actual operation the time is dependent on additional factors including the speed of the wavelength(s) of light in air and through various optical surfaces, the geometry between the short pulse laser illuminator 310 and the optical system elements 340, 350 and detector 360 element(s).

The speed of light in air is approximately 2.997925×10¹⁰ centimeters per second which equates to 3.335604 meters per nanosecond. A resolution in time of one picosecond would provide an optical path resolution of approximately 3.36 centimeters, one tenth of a picoseconds resolution results in a resolution of approximately 3.36 millimeters, one hundredth of a picoseconds resolution results in a resolution of approximately 336 microns, and one femtosecond resolution results in a resolution of approximately 33.6 microns.

The detector 360 is operatively connected 370 to the signal processing and control module 120 which is then further operatively connected to the user interface 130. A sync signal or command interface 380 provides timing synchronization between the short pulse laser illuminator 310 and the detector. A portable power source 390 is optional but required for mobile implementations. The power source may be any form of battery, fuel cell, generator, or energy link such as antenna that gathers energy from an imposed field.

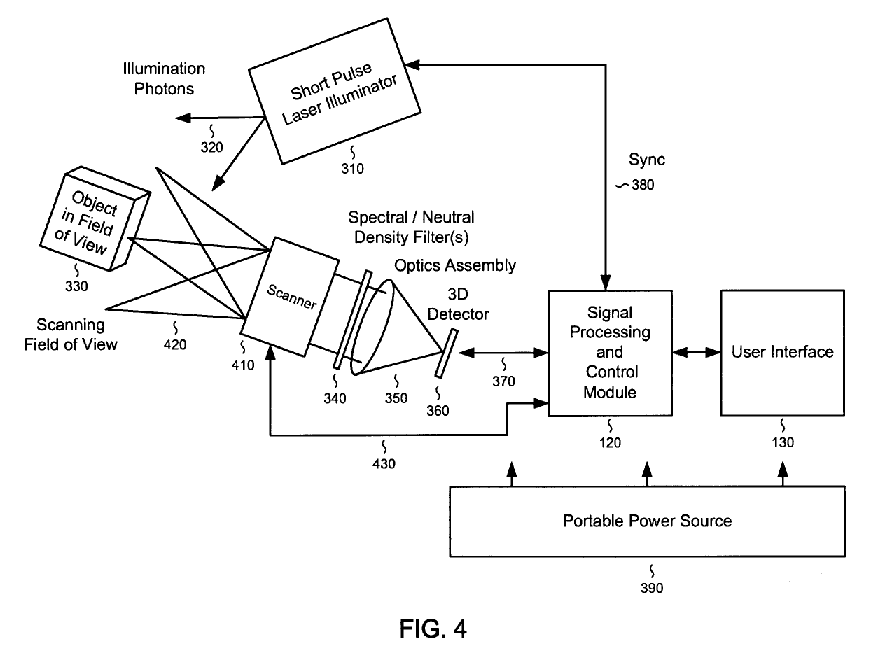

Referring to FIG. 4, a block diagram of a vision augmentation system is presented which incorporates the use of a scanning system 410 to scan the instantaneous field of view of the detector. It should be noted for purposes of the present invention that when referring to the instantaneous field of view it may generated by use of the optical system, scanner, and the entire detector or some portion of the detector which may be as small or smaller than a single pixel element. A short pulse laser illuminator 310 that provides illumination photons 320 to a field of view. The illumination photons 320 are then impingent upon an object or surface in the field of view and are either reflected, transmitted, or absorbed by the object or surface. Reflected photons that are backscattered into the scanner's instantaneous field of view 420 are collected by the optical system 350 with or without the aid of a spectral filter 340. The instantaneous field of view 420 is typically governed by the optical system design 350, overall detector size 360, and scanning mechanism 410. The ability to scan the instantaneous field of view 420 over the entire desired field of view is one limiting element of the bandwidth of the entire system. While it is possible to scan the instantaneous field of view 420 over the entire field of view, other scan techniques are equally applicable. One scan technique is the limiting of the instantaneous field of view scan to some subset of the total field of view. Another technique is to dwell on one particular point in the field of view. Yet another technique is to change the scan rate to provide higher resolutions in some portion of the field of view and lower resolution in other portions of the field of view.

There are numerous techniques well known in the to perform two dimensional scanning including, but not limited to azimuth and elevation and X,Y scanners. The scanning mechanism may include, but are not limited to, any form of mechanical, solid state, gas, or chemical scanning means including galvanometers, piezoelectric actuators, and advantageously micro-electro-mechanical systems (MEMS) devices. The scanner 410 may also receive commands and control and provide position feedback 430 to the signal processing and control module 120.

The optical system 350 then collects one or more photons and presents these photons to a detector 360 capable of resolving spatial depth information. The detector 360 is operatively connected 370 to the signal processing and control module 120 which is then further operatively connected to the user interface 130. A sync signal or command interface 380 provides timing synchronization between the short pulse laser illuminator 310 and the detector. A portable power source 390 is optional but required for mobile implementations.

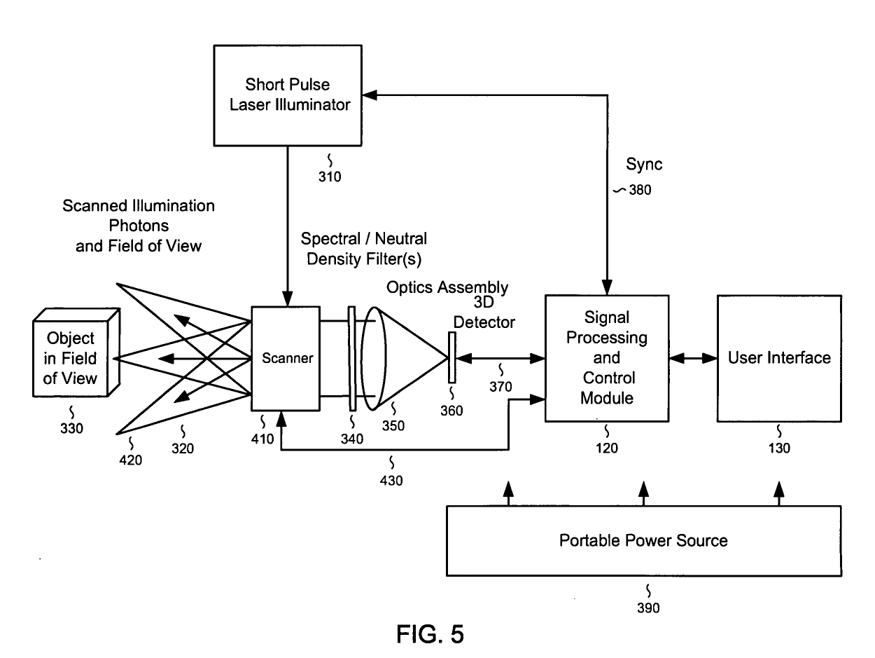

Referring to FIG. 5, a block diagram of a vision augmentation system is presented which incorporates the use of a scanning system 410 to scan the instantaneous field of view of both the detector 360 and illuminator 310. A short pulse laser illuminator 310 provides illumination photons 320 to a scanner that scans both the illumination source 310 and the detector's 360 optical field of view. Advantageously, this system directs the illumination energy out into the object space co-linear and synchronously with the detector's instantaneous field of view. A single scanner is preferred, but multiple synchronous scanners may also be employed.

Once again, the illumination photons 320 are then impingent upon an object or surface in the field of view and are either reflected, transmitted, or absorbed by the object or surface. Reflected photons that are backscattered into the scanner's instantaneous field of view 420 are collected by the optical system 350 with or without the aid of a spectral filter 340. The scanner 410 may also receive commands and control and provide position feedback 430 to the signal processing and control module 120. The optical system 350 then collects one or more photons and presents these photons to a detector 360 capable of resolving spatial depth information. The detector 360 is operatively connected 370 to the signal processing and control module 120 which is then further operatively connected to the user interface 130. A sync signal or command interface 380 provides timing synchronization between the short pulse laser illuminator 310 and the detector. A portable power source 390 is optional but required for mobile implementations.

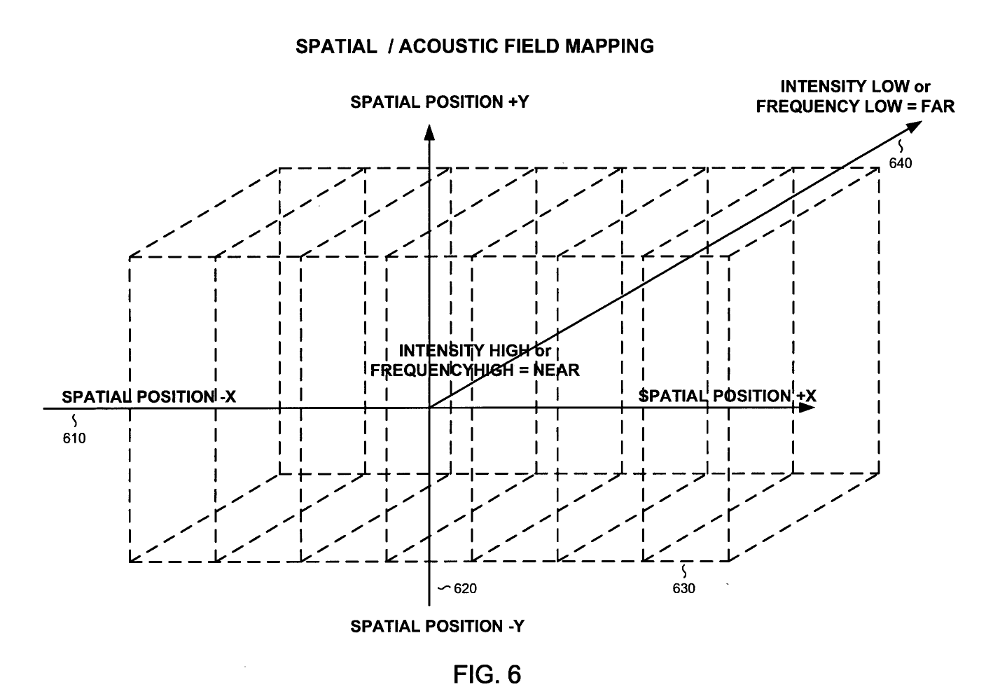

Referring to FIG. 6, a block diagram of three dimensional object or surface information presented to a user via a user interface by generating an audio acoustic field 630. Spatial position from a central reference point is generated by the intersection of the X axis 610 the Y axis 620. Depth information may be presented as intensity of the acoustic signal 640, frequency or the acoustic signal 640, or some combination thereof. Advantageously, louder acoustic signals or higher frequencies are proportionately near and softer acoustic signals or lower frequencies proportionately far. Modulation of a single frequency may also be employed—faster repetition meaning closer and slower repetition meaning farther. The mapping of the object or surface location may be by a simple Cartesian coordinate system as shown, a spherical coordinate system, a cylindrical coordinate system, a curvilinear coordinate system, or via any useful mapping function desired. For example, amplitude may follow a function which models human hearing response to amplitude or frequency, or some combination thereof.

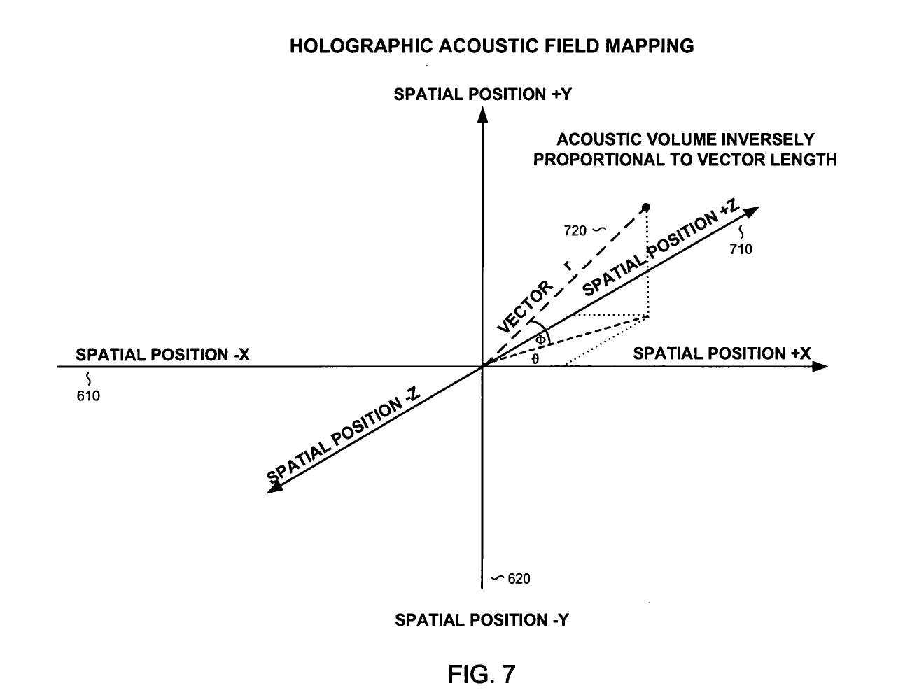

Referring to FIG. 7, a block diagram of three dimensional object or surface information presented to a user via a user interface by generating a holographic audio acoustic field 630. Spatial position from a central reference point is again created by the intersection of the X axis 610, the Y axis 620, and the Z axis 710. Depth information may be presented as intensity of the acoustic signal 640, frequency or the acoustic signal 640, modulation of the acoustic signal, or some combination thereof. As shown, a vector r 720 is utilized to scale the distance representation. This technique has the advantage of being able to render object and surface positions in an entire 4π steradian field of view.

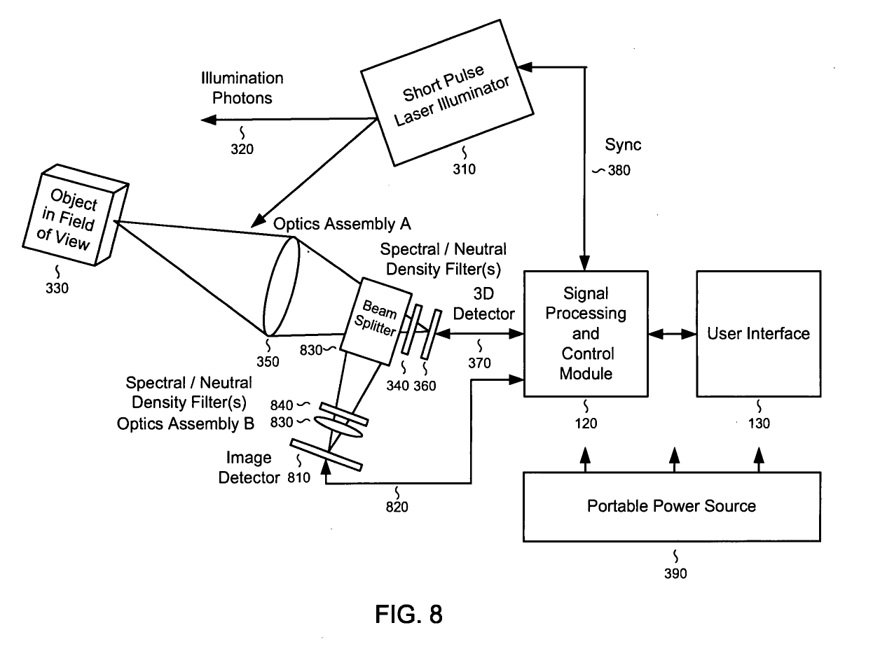

Referring to FIG. 8, a block diagram of a vision augmentation system is presented which incorporates the use of a beam splitter 830 that allows for simultaneous operation of a ladar 3D detector 360 along with a visible, ultraviolet, or infrared image detector 810 sharing some or all of the same field of view. As shown, a beam splitter which may divide the energy impingent on it from the optics assembly 350 based upon a proportion (such as 50/50) or dichroically according to wavelength, or via time division multiplexing, or any other mutually advantageous sharing arrangement. The image detector 810 may utilize its own optical assembly 830 and/or spectral and neutral density filters 840. It may be operated asynchronously or synchronously. Advantageously, it may operate synchronously interleaved into time periods when the short pulse illuminator 310 is inoperative for illuminated scenes or utilized simultaneously with the illuminator operative for illumination of dark scenes. The image detector 810 is operatively coupled 820 to the signal processing and control module 120 which may provide command and control information. While not shown, the beam splitter 830 may also be operatively coupled to the signal processing and control module 120 which may provide command and control information such as time division multiplexing signals and election of operating wavelengths. Additionally, scanners may be utilized for either detector's field of view, or for both combined. Further, the two detectors need not share a single aperture or optical system, indeed two or more optical systems may be utilized. To achieve higher resolution over a given field of view multiple spatial or image detectors may share the same optical system. For example, three image detectors may be utilized to achieve red, green, blue color detection in combination with a single spatial detector for range information. The invention is not limited to any particular combination of detectors or optical configurations.

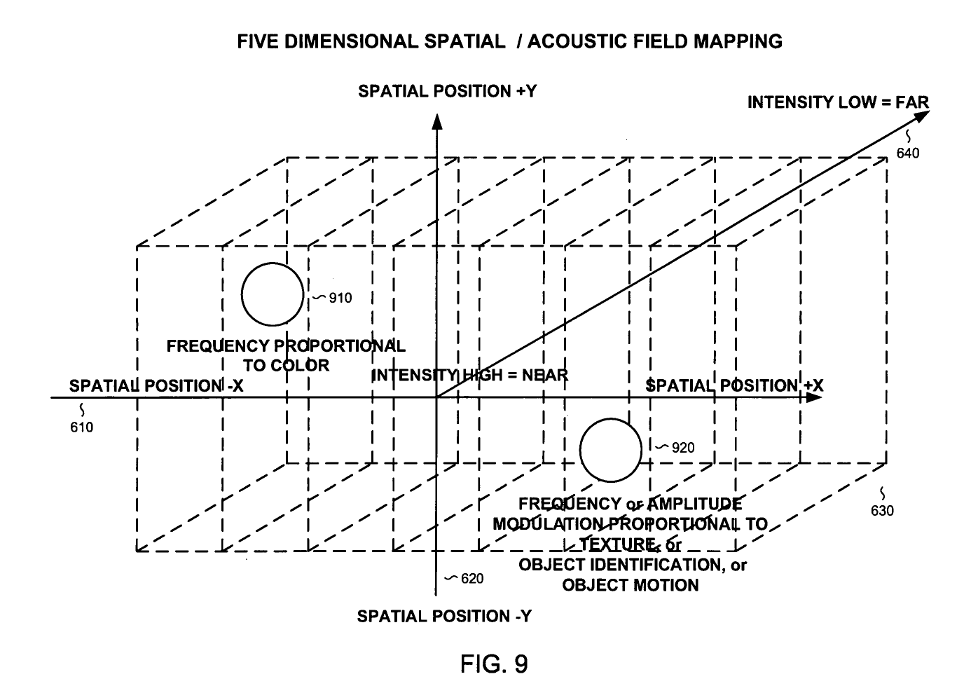

Referring to FIG. 9, a block diagram of three dimensional object or surface information along with color represented as frequency and modulation to represent object information such as texture or object identification presented to a user via a user interface by generating an audio acoustic field 630. Spatial position from a central reference point is generated by the intersection of the X axis 610 the Y axis 620. Depth information may be presented as intensity of the acoustic signal 640, color may be represented by frequency 910, object or surface texture, identification or motion may be represented by amplitude or frequency modulation 920. Advantageously, louder acoustic signals are nearer and softer acoustic signals are farther, however any combination of amplitude, frequency, or modulation mapping in the three dimensional space may be utilized as appropriate. Once again the mapping of the object or surface location may be by a simple Cartesian coordinate system as shown, a spherical coordinate system, a cylindrical coordinate system, a curvilinear coordinate system, or via any useful mapping function desired. For example, amplitude may follow a function which models human hearing response to amplitude or frequency, or some combination thereof. Advantageously, a holographic acoustic imaging system may be employed.

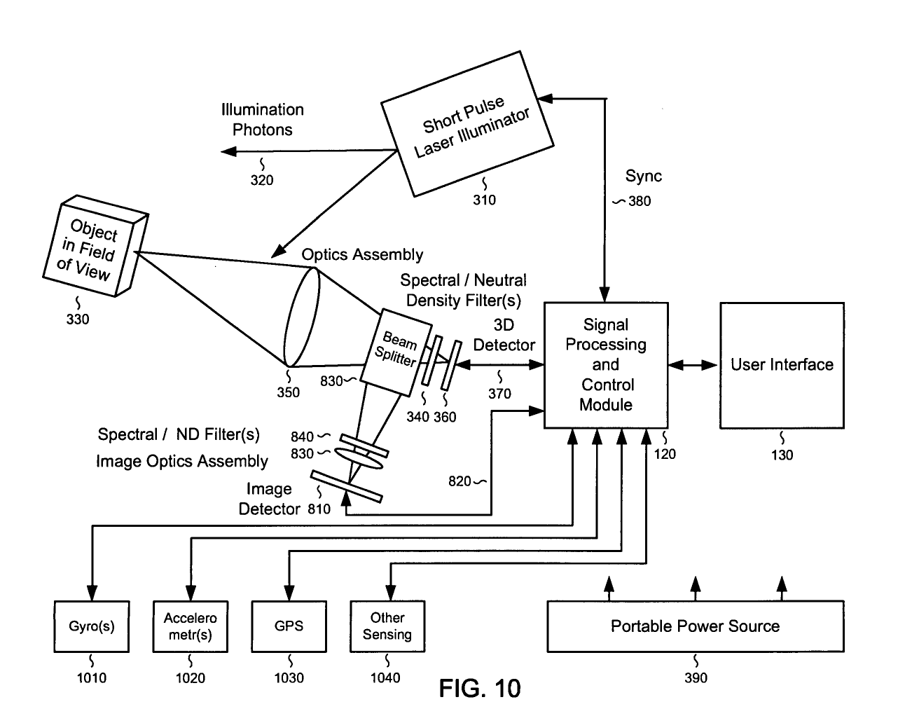

Referring to FIG. 10, a block diagram of a vision augmentation system that includes additional sensing technologies such as gyros or inertial measuring units, 1010 accelerometers 1020, global positioning system receivers 1020, and other forms of attitude or tactile sensing which are operatively coupled to the signal processing and control module 120. Gyros or inertial measuring units 1010 and accelerometers 1020 provide the ability to track instantaneous relative motion. This information may be advantageously combined with sensed depth or image motion. For example, small movements such as twitches or shaking may be removed from the depth information display. Head motion may be monitored and the focus of one or more optical systems adjusted for the expected user geometry. An acoustical multi-dimensional spatial, textural, object placement, object parameter, or color mapping that is user position or attitude centric may be presented to the user that is independent of the position or movement of the users head or body orientation. In addition, object or surface positions may be created from a known starting point such as from a GPS sensor 1030. Alternately the GPS sensor 1030 may be utilized to provide situation awareness of upcoming obstacles or terrain changes by combining a three dimensional spatial map database with or without current depth information. Wide area augmentation GPS systems are particularly good at resolving small distances required for navigating local obstacles or terrain. Other tactile and attitude sensing devices may be utilized in combination with spatial or image sensing.

Although illustrative embodiments have been described herein with references to the accompanying drawings, it is to be understood that the present invention is not limited those precise embodiments, and that various other changes and modifications may be affected therein by one skilled in the art without departing from the spirit or scope of the invention as defined by the appended claims.

What is claimed is:

1. A system for vision augmentation comprising:
a laser imaging radar system;
a signal processing and control module; and
an acoustical user interface.

2. The system of claim 1 wherein the laser imaging radar system is operatively connected to the signal processing and control module.

3. The system of claim 1 wherein the signal processing and control module is selected from the group consisting of: dedicated analog or digital hardware, digital signal processors, general purpose processors, software, firmware, microcode, memory devices of all forms, and data input or output interfaces.

4. The system of claim 1 wherein the signal processing and control module is operatively connected to the user interface to present spatial location information.

5. The system of claim 1 wherein the laser imaging radar utilizes a solid state laser.

6. The system of claim 5 wherein the solid state laser is a passively Q-switched frequency doubled Nd:Yag laser.

7. The system of claim 1 wherein the laser imaging radar utilizes a geiger mode avalanche photodiode detector array.

8. The system of claim 1 wherein the laser imaging radar system utilizes a static imaging system.

9. The system of claim 1 wherein the laser imaging radar system utilizes a scanning imaging system.

10. The system of claim 1 wherein the laser imaging radar system utilizes a beam splitter.

11. The system of claim 1 wherein the laser imaging radar system is a micro pulse laser imaging radar system.

12. The system of claim 1 wherein the acoustical user interface presents depth information and object location information acoustically by sweeping the audio acoustic field to present depth as frequency and the audio image as location creating a depth/azimuth/elevation presentation.

13. The system of claim 1 wherein the acoustical user interface utilizes holographic acoustical imaging to present three dimensional image information.

14. The system of claim 1 wherein the acoustical user interface utilizes holographic acoustical imaging to present three, four, five, or greater dimensional image information.

15. The system of claim 1 further comprising a portable power source.

16. The system of claim 1 further comprising a plurality of sensing technologies selected from the group consisting of gyros, inertial measuring units, accelerometer, global positioning system receivers, and a combination thereof, wherein the plurality of sensing technologies are operatively coupled to the signal processing and control module.

17. The system of claim 1 wherein the vision augmentation system is housed in a pair of corrective lenses.

18. A method for vision augmentation comprising:
viewing an optical field of view with a laser imaging radar system;
determining spatial information concerning one or more objects in the field of view presenting the spatial information to the user on an acoustical user interface.

19. The method of claim 18 further comprising:
utilizing a plurality of co-operative retro reflectors or reflective coatings on the one or more objects in the field of view.

20. A method for vision augmentation comprising:
viewing an optical field of view with a laser imaging radar system;
viewing part or all of the same optical field of view with an imaging sensor;
determining spatial location information concerning one or more objects in the field of view;
determining additional information, such as color, texture, motion or object recognition; and
providing the spatial location information to the user on an acoustical user interface in a three, four or five dimensional acoustical format utilizing three dimensional acoustic position information, along with frequency, and modulation to represent color, texture, object recognition or object motion information to assist the blind or visually impaired.
